(19) United States
(12) Patent Application Publication
(10) Pub. No.: US 2017/0068467 A1
(43) Pub. Date: Mar. 9, 2017

(54) WEAR MANAGEMENT FOR FLASH MEMORY DEVICES

(71) Applicant: HGST Netherlands B.V., Amsterdam (NL)

(72) Inventor: Michael Stephen ROTHBERG, Foothill Ranch, CA (US)

(21) Appl. No.: 14/846,540

(22) Filed: Sep. 4, 2015

(51) Int. Cl. G06F 3/06; G11C 16/34

(52) U.S. Cl. CPC G06F 3/0616; G11C 16/3495; G06F 3/0653; G06F 3/0688

(57) ABSTRACT

A machine-implemented method for managing a flash storage system includes receiving a command for a data operation. The method includes determining a projected life value for each of a plurality of flash memory devices in the flash storage system, wherein the projected life value for at least one of the plurality of flash memory devices is higher than the projected life value for at least another one of the plurality of flash memory devices. The method also includes selecting a flash memory block on one of the plurality of flash memory devices for the data operation based on the respective projected life values for the plurality of flash memory devices.

### BACKGROUND

The present disclosure concerns flash storage systems and, more particularly, optimized wear leveling for flash memory devices.

Flash storage systems, such as solid-state drives (SSDs), use flash memory as a non-volatile storage medium. A flash storage system may include multiple flash memory devices. The flash memory devices are programmed (e.g., written to) as data is stored, and erased when space on the flash memory devices is freed. A flash memory device has a limited number of program/erase (P/E) cycles the flash memory device can withstand before becoming unusable.

### SUMMARY

The subject technology optimizes data wear leveling in a flash storage system by selecting a flash memory device for a data operation based on a projected life value for the flash memory device. The projected life value may be determined through testing the flash memory device.

According to aspects of the subject technology, a machine-implemented method for managing a flash storage system is provided. The method includes receiving a command for a data operation. The method also includes determining a projected life value for each of a plurality of flash memory devices in the flash storage system, wherein the projected life value for at least one of the plurality of flash memory devices is higher than the projected life value for at least another one of the plurality of flash memory devices. The method also includes selecting a flash memory block on one of the plurality of flash memory devices for the data operation based on the respective projected life values for the plurality of flash memory devices.

According to other aspects of the subject technology, a flash storage system is provided. The flash storage system includes a plurality of flash memory devices and a controller. Each of the plurality of flash memory devices has a projected life value, wherein the projected life value for at least one of the plurality of flash memory devices is higher than the projected life value for at least another one of the plurality of flash memory devices. The controller is configured receive a command for a data operation, and select a flash memory block on one of the plurality of flash memory devices for the data operation based on the respective projected life values for the plurality of flash memory devices comprising a plurality of flash memory blocks.

According to other aspects of the subject technology, a machine-readable media is encoded with executable instructions which, when executed by a processor, cause the processor to perform operations. The operations include determining an order of a plurality of flash memory devices based on a projected life value for each of the plurality of flash memory devices in the flash storage system, wherein the projected life value for at least one of the plurality of flash memory devices is higher than the projected life value for at least another one of the plurality of flash memory devices. The operations also include receiving a command for a data operation. The operations also include selecting one of the plurality of flash memory devices based on the order of the plurality of flash memory devices. The operations also include selecting a flash memory block on the selected one of the plurality of flash memory devices for the data operation.

It is understood that other configurations of the subject technology will become readily apparent to those skilled in the art from the following detailed description, wherein various configurations of the subject technology are shown and described by way of illustration. As will be realized, the subject technology is capable of other and different configurations and its several details are capable of modification in various other respects, all without departing from the scope of the subject technology. Accordingly, the drawings and detailed description are to be regarded as illustrative in nature and not as restrictive.

### BRIEF DESCRIPTION OF THE DRAWINGS

FIG. 1 is a block diagram illustrating components of a flash storage system according to aspects of the subject technology.

FIG. 2 is a flowchart illustrating a method for managing a flash storage system according to aspects of the subject technology.

FIG. 3A is a table showing P/E cycles in an even wear leveling scheme according to aspects of the subject technology.

FIG. 3B is a table showing P/E cycles in an optimized wear leveling scheme according to aspects of the subject technology.

FIG. 4 is a flowchart illustrating a method for managing a flash storage system according to aspects of the subject technology.

### DETAILED DESCRIPTION

The detailed description set forth below is intended as a description of various configurations of the subject technology and is not intended to represent the only configurations in which the subject technology may be practiced. The appended drawings are incorporated herein and constitute a part of the detailed description. The detailed description includes specific details for the purpose of providing a thorough understanding of the subject technology. However, the subject technology may be practiced without these specific details. In some instances, structures and components are shown in block diagram form in order to avoid obscuring the concepts of the subject technology.

A flash storage system such as a solid-state drive (SSD) includes one or more flash memory devices, each of which may comprise one or more dies. Each flash memory device or die comprises an array of flash memory cells. Each memory cell includes a floating gate transistor that is used to store one or more bits of data. The flash memory cells may be organized into blocks, with each physical block comprising a number of pages. Data is written to flash memory in write units of pages. Data is erased from flash memory in erase units of blocks. Each P/E cycle may physically degrade or wear down the flash memory cells of a block such that each block has a finite number of P/E cycles before the wear deteriorates the integrity and reliability of data storage in the block.

Flash storage systems may be rated or tiered based on life expectancy, corresponding to P/E cycle limits of the blocks in the flash storage system. In order to construct a flash storage system of a certain life expectancy, flash memory devices having similar life expectancies are selected for the flash storage system. Manufacturers of flash memory devices may select a small sample of dies from a batch of dies for testing, and based on the testing designate every die in the batch with a manufacturer life value. The manufacturer life value may correspond to a lowest expected life value (e.g., number of P/E cycles) for the dies in the batch. In other words, the manufacturer life value may correspond to a number of P/E cycles in which at least a minimum number of blocks is expected—to a high degree of certainty such as 90% or 99%—to provide the performance of the number of P/E cycles. Each block in a die, or a minimum number of blocks in the die, or an average block across the blocks in the die, is expected to last at least as long as the designated manufacturer life value. For example, the manufacturer may rate the tested batch at 30,000 P/E cycles. Each block of the flash memory devices in the tested batch would be expected on average to last at least 30,000 P/E cycles. For example, certain blocks may last more than 30,000 P/E cycles, and certain other blocks may last less than 30,000 P/E cycles, but on average the blocks may last 30,000 P/E cycles.

The flash storage system may utilize the flash memory devices based on the manufacturer life value. However, each flash memory device in the flash storage system may have actual life values that are different from the manufacturer life values. Projected life values for each flash memory device, which may be estimates of the actual life values determined through individual device testing, may be more accurate representations of actual life values than the manufacturer life values. The flash storage system may utilize the flash memory devices differently based on the projected life values.

Conventional wear leveling schemes may operate on the assumption that all flash memory devices in a flash storage system have the same life expectancy, based on the manufacturer life value. If the same block of a flash memory device is selected for a data operation (e.g., is programmed/erased) more often than other blocks in the flash storage system, the selected block may fail much sooner than the other blocks. If a sufficient number of blocks in a flash memory device fails, the flash memory device may be rendered unusable. Flash storage systems utilize wear leveling schemes when selecting a block of a flash memory device for a data operation in order to better distribute the wear, and prevent one or more blocks and/or flash memory devices from failing significantly sooner than the other blocks and/or flash memory devices in the flash storage system. Failure of blocks and/or flash memory device compromise the performance of the flash storage system.

Wear leveling schemes may distribute wear so that all of the flash memory devices fail around the same time, which conventionally corresponds to the manufacturer life value. However, because the manufacturer life value may be a conservative floor value representing the lowest expected life value, the actual life value for each flash memory device may be different from the manufacturer life value. When the actual life values of one or more flash memory devices are greater than the manufacturer life value, the additional life (e.g., P/E cycles in excess of the manufacturer life value) may be unused. The wear leveling scheme may be optimized by utilizing the flash memory devices differently based on projected life values in order to take advantage of different actual life values of the flash memory devices.

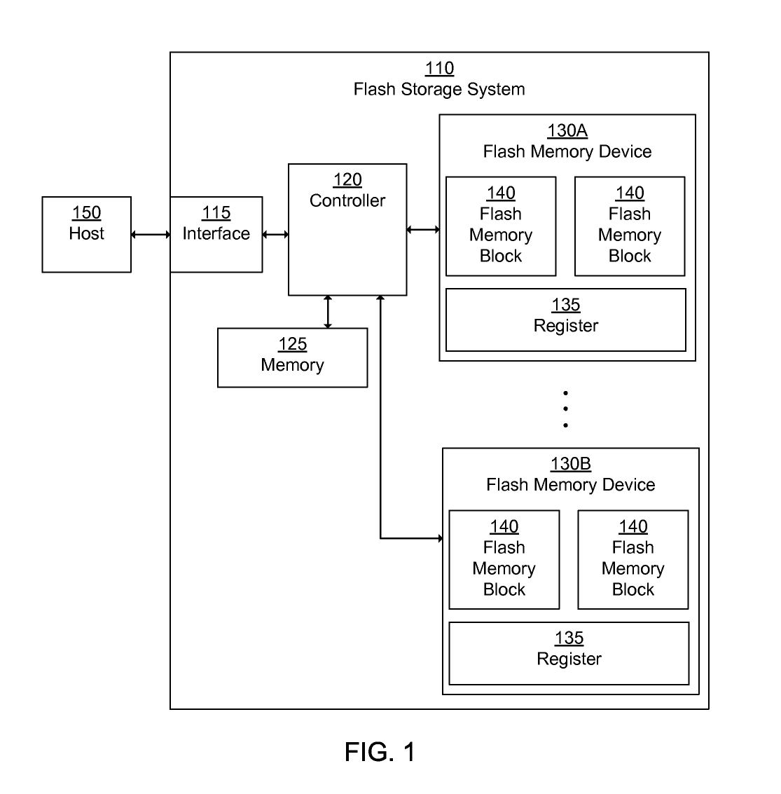

FIG. 1 is a block diagram illustrating components of a flash storage system 110 according to aspects of the subject technology. As depicted in FIG. 1, the flash storage system 110 includes an interface 115, a controller 120, a flash memory device 130A and a flash memory device 130B (collectively flash memory devices 130), and a memory 125. The interface 115 facilitates communication of data, commands, and/or control signals between the flash storage system 110 and a host 150. The controller 120 controls the operation of the flash storage system 110 to store and retrieve data in the flash memory devices 130 in accordance with commands received from the host 150. The controller 120 may include a processor. The memory 125, which may be a random access memory (RAM), provides temporary storage space for the controller 120 to process commands and transfer data between the host 150 and the flash memory devices 130. The operation of each of these components is described in more detail below.

The interface 115 provides physical and electrical connections between the host 150 and the flash storage system 110. The interface 115 is configured to facilitate communication of data, commands, and/or control signals between the host 150 and the flash storage system 110 via the physical and electrical connections. The connection and the communications with the interface 115 may be based on a standard interface such as Universal Serial Bus (USB), Small Computer System Interface (SCSI), Serial Advanced Technology Attachment (SATA), etc. Alternatively, the connection and/or communications may be based on a proprietary interface, although the subject technology is not limited to any particular type of interface.

The host 150 may be a computing device, such as a computer/server, a smartphone, or any other electronic device which reads data from and writes data to the flash storage system 110. The host 150 may have an operating system or other software that issues read and write commands to the flash storage system 110. The flash storage system 110 may be integrated with the host 150 or may be external to the host 150. The flash storage system 110 may be wirelessly connected to the host 150, or may be physically connected to the host 150.

FIG. 1 shows two flash memory devices 130 (the flash memory device 130A and the flash memory device 130B). However, the flash storage system 110 may include more than two flash memory devices 130 and is not limited to two flash memory devices 130. The flash memory devices 130 may each include a single flash memory chip or die. The flash memory devices 130 may be organized among multiple channels through which data is read from and written to the flash memory devices 130 by the controller 120, or coupled to a single channel. The flash memory devices 130 may be implemented using NAND flash memory. The flash memory devices 130 may each comprise a register 135, which may be one or more registers for storing data, such as operating parameters of the respective flash memory devices 130. The operating parameters may include: write operation parameters such as initial pulse value, incremental pulse value, and pulse width; erase operation parameters such as initial pulse value, incremental pulse value, and pulse width; and read operation parameters such as read level voltage.

The flash memory devices 130 comprise multiple memory cells distributed into storage blocks such as flash memory blocks 140. Although FIG. 1 shows the flash memory devices 130 each having two flash memory blocks 140, the flash memory devices 130 may have more or less flash memory blocks 140, and the flash memory devices 130 may each have the same or different numbers of flash memory blocks 140. The flash memory blocks 140 may be referred to as data blocks or memory blocks and are addressable by the controller 120 using a physical block address. Each of the flash memory blocks 140 is further divided into multiple data segments or pages addressable by the controller 120 using a physical page address or offset from a physical block address of the storage block containing the referenced page. The pages may store sectors or other host data units. The flash memory blocks 140 represent the units of data that are erased within the flash memory devices 130 in a single erase operation. The pages represent the units of data that are read from or written to the flash memory devices 130 in a read or write operation. Although the flash memory devices 130 are described in terms of blocks and pages, other terminology may be used to refer to these data units within a flash storage device.

The subject technology is not limited to any particular capacity of flash memory. For example, storage blocks may each comprise 32, 64, 128, or 512 pages, or any other number of pages. Additionally, pages may each comprise 512 bytes, 2 KB, 4 KB, or 32 KB, for example. The sectors may each comprise, for example, 512 bytes, 4 KB, or other sizes. There may be one or more sectors per page.

In FIG. 1, the memory 125 represents a volatile memory coupled to and used by the controller 120 during operation of the flash storage system 110. The controller 120 may buffer commands and/or data in the memory 125. The controller 120 also may use the memory 125 to store address mapping tables or lookup tables used to convert logical data addresses used by the host 150 into virtual and/or physical addresses corresponding to portions of the flash memory devices 130. Other types of tables, data, status indicators, etc. used to manage the flash memory devices 130 may also be stored in the memory 125 by the controller 120. For example, characteristics of the flash memory devices 130 include data used for wear leveling, such as P/E cycle counts for each flash memory block 140, error counts for each flash memory block 140, and retention times for each flash memory block 140. The memory 125 may be implemented using dynamic random access memory (DRAM), static random access memory (SRAM), or other types of volatile random access memory without departing from the scope of the subject technology. The controller 120 may periodically store the contents of the memory 125 into one or more designated flash memory blocks 140, such as before the flash storage system 110 is powered down.

The controller 120 manages the flow of data between the host 150 and the flash memory devices 130. The controller 120 is configured to receive commands and data from the host 150 via the interface 115. For example, the controller 120 may receive data and a write command from the host 150 to write the data in the flash memory devices 130. The controller 120 is further configured to send data to the host 150 via the interface 115. For example, the controller 120 may read data from the flash memory devices 130 and send the data to the host 150 in response to a read command. The controller 120 is further configured to manage data stored in the flash memory devices 130 and the memory 125 based on internal control algorithms or other types of commands that may be received from the host 150. For example, the controller 120 is configured to perform operations such as garbage collection (GC), error correction, and wear leveling. Those skilled in the art will be familiar with other operations performed by a controller in a flash storage device, which will not be described in detail herein.

The controller 120 may be implemented with a general purpose processor, micro-controller, digital signal processor (DSP), a system-on-a-chip (SoC), an application specific integrated circuit (ASIC), a field programmable gate array (FPGA) or other programmable logic device, discrete gate or transistor logic device, discrete hardware components, or any combination thereof designed and configured to perform the operations and functions described herein. The controller 120 may perform the operations and functions described herein by executing one or more sequences of instructions stored on a machine/computer readable medium. The machine/computer readable medium may be the flash memory devices 130, the memory 125, or other types of media from which the controller 120 can read instructions or code. For example, flash storage system 110 may include a read only memory (ROM), such as an EPROM or EEPROM, encoded with firmware/software comprising one or more sequences of instructions read and executed by the controller 120 during the operation of the flash storage system 110.

The controller 120 may perform maintenance operations on the flash memory devices 130 during idle times, such as between commands from the host 150. For example, the controller 120 may determine that GC is necessary to free up one of the flash memory blocks 140 for a data operation. A flash memory block 140 may be selected for GC based on a wear leveling scheme. Because of the limited P/E cycles of blocks, using a specific block more often than other blocks may cause that specific block to fail before the other blocks. Failure may be determined if a block produces unrecoverable read errors.

The controller 120 may keep track of the P/E cycle count of each flash memory block 140 for wear leveling purposes. In an even wear leveling scheme, a flash memory device 130 with flash memory blocks 140 having the lowest P/E cycle count may be selected for a data operation, to evenly distribute the wear from P/E cycles. Even wear leveling schemes may not consider actual or projected life values of the flash memory devices, and operate on the assumption that the flash storage system 110 generally comprises flash memory devices having similar life expectancies without accounting for possible variation.

However, each individual flash memory device 130 may have an actual life value above or below the manufacturer life value. Therefore, even wear leveling schemes may lead to less than optimal performance. For instance, if one or more flash memory devices 130 has an actual life value below the manufacturer life value, the flash storage system 110 may fail earlier than expected. If one or more flash memory devices 130 has an actual life value above the manufacturer life value, the additional P/E cycles beyond the manufacturer life value may not be utilized. An optimal wear leveling scheme may be based on projected life values which may be similar to the actual life values for the flash memory devices to take advantage of additional cycles beyond the manufacturer life value.

In addition, a flash storage system may be rated or classified based on a life expectancy of the flash storage system. Flash memory devices having high P/E cycle expectancies may be expected to have a long life for use in an enterprise storage system, or may be used in a high performance system which sacrifices long life for faster program/erase speeds. Flash memory devices having low P/E cycle expectancies may be used in low performance systems with lower life expectancies or slower speeds.

The projected life value may correspond to a number of P/E cycles expected to be performed on the flash memory blocks of the flash memory device before failure of the flash memory blocks. Individual testing of each flash memory device may determine projected life values, which may be more accurate estimates of actual life values than the manufacturer life value.

Conventional testing methods used by manufacturers during batch testing may be impractical or unfeasible for individually testing each flash memory device. Conventional testing may be based on applying a conventional write or erase voltage based on conventional parameters. The conventional parameters available on flash memory devices may allow testing of assembly of the flash memory device. A high voltage may be a voltage greater than one or both of the conventional write voltage and the conventional erase voltage, e.g., a maximum voltage available on the flash memory device.

A high voltage test may be faster than conventional tests, and therefore may be more feasible to conduct on each individual flash memory device. The high voltage test may comprise applying a high voltage for long durations (e.g., durations of time longer than conventional pulse durations) and/or multiple pulses in order to speed up charge capture in the memory cells of the block and reach a saturation point of charge capture. In addition, rather than waiting for a cool off period between pulses, the pulses may be applied consecutively, which may further speed the time to reach the saturation point. The voltage parameters, such as number of pulses at the high voltage, may be measured and used to determine a projected life value that is closer to the actual life value than the manufacturer life value. For example, empirical data may be derived from simulation or lab data correlating saturation points with life expectancy, or may be collected from performing the high voltage test on various flash memory devices to correlate the voltage parameters, time to reach saturation point, and other characteristics to expected P/E cycle counts. The projected life value corresponds to the expected P/E cycle count.

The high voltage test may be run until the end of the life of the tested block, which renders the tested block unusable. However, flash memory devices may be manufactured with extra blocks to account for block failures or use in maintenance operations. To reduce the effects of location variation within the blocks, the same blocks on the same locations on each flash memory device may be tested.

Using the projected life values, flash memory devices may be better matched for assembly in flash storage systems. Alternatively, flash storage systems may be assembled before the projected life value for each flash memory device is tested. The projected life values may better determine a performance tier of the flash storage system. For instance, if the projected life values of the flash memory devices of a flash storage system are generally all higher or all lower than expected based on the manufacturer life value (which may have been used for the initial assembly of the flash storage system), the flash storage system may be rated a higher tier or lower tier accordingly. If the projected life values are mixed such that some projected life values are higher than the manufacturer life value, and some projected life values are lower than the manufacturer life value, the higher performance of the flash memory devices having projected life values higher than the manufacturer life value may offset the lower performance of the flash memory devices having projected life values lower than the manufacturer life value, and the flash storage system can be accordingly rated based on the averaged performance.

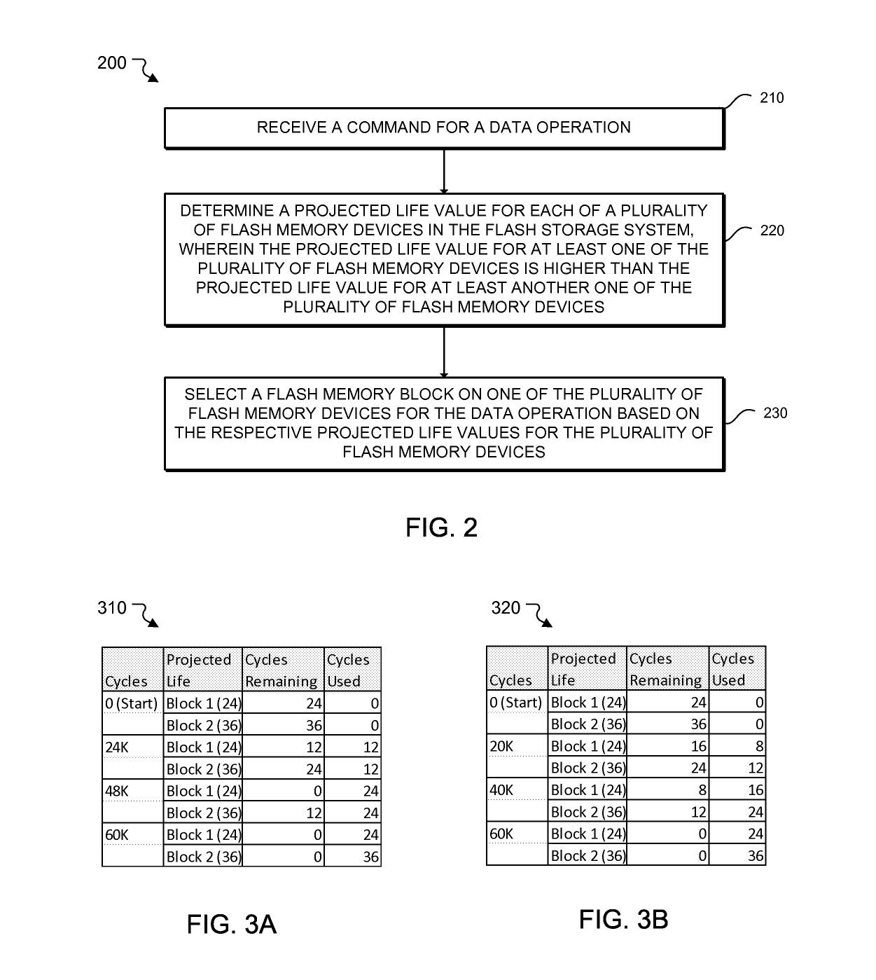

An optimal wear leveling scheme may optimize the use of available P/E cycles in excess of the manufacturer life value. FIG. 2 shows a flowchart 200 for a wear leveling scheme according to aspects of the subject technology. The process in FIG. 2 may be performed, for example, by the controller 120 of the flash storage system 110. The flash storage system 110 is assembled with a plurality of flash memory devices 130 having the same or similar manufacturer life value. Each flash memory device 130 is individually tested with the high voltage test to determine respective projected life values, which is stored in the memory 125, and may be stored in a designated flash memory block 140 associated with the memory 125. The projected life values may be stored with respect to each flash memory device 130 (such that the projected life value is propagated or otherwise associated with respective flash memory blocks 140) or stored with respect to each flash memory block 140 based on the corresponding flash memory device 130. At least one of the projected life values is different from the manufacturer life value. For instance, the projected life value of the flash memory device 130A is higher than the manufacturer life value.

At 210, a command for a data operation is received. The controller 120 may receive a read, write, or erase command from the host 150, such as a write operation to write host data from the host 150 to a flash memory block 140. Alternatively, rather than receiving the command from the host, the command may be for a maintenance operation to be performed by the controller 120, such as a GC process to reclaim invalid memory locations in a flash memory block 140.

At 220, a projected life value is determined for each of a plurality of flash memory devices in the flash storage system, wherein the projected life value for at least one of the plurality of flash memory devices is higher than the projected life value for at least another of the plurality of flash memory devices. Although the flash memory devices may have been initially selected for inclusion in the flash storage system based on similar manufacturer life values, individual die testing may reveal variations in the projected life values for each flash memory device. The individual die testing may reveal that the projected life values differ from the manufacturer life value, and may also differ among the flash memory devices.

The projected life value may have been previously calculated through the high voltage test, and stored in a memory of the flash storage system. The projected life value may be determined through reading the value stored in the memory, such as a memory associated with the controller, a designated block on the corresponding flash memory device, or stored on another memory in the flash storage system. Alternatively, the projected life value may be determined indirectly. For instance, the controller may keep track of the flash memory devices through a data structure. The controller may order the flash memory devices in a linked list based on the projected life values. A position for a flash memory device in the linked list may correspond to the projected life value of the corresponding flash memory device, such that flash memory devices having more remaining cycles may be positioned near a beginning of the linked list. The linked list may be updated after each data operation such that a flash memory device selected for a data operation may be repositioned in the linked list after the data operation. The repositioning may be based on an updated value for remaining cycles.

In the flash storage system 110, the controller 120 determines the projected life value of a flash memory device 130 by reading a projected life value for the flash memory device 130 stored in the memory 125. The projected life values may have been previously stored on a designated flash memory block 140, which may be subsequently read into the memory 125. The projected life value for a flash memory device 130 is associated with each flash memory block 140 on the respective flash memory device 130. The projected life value may correspond to a number of P/E cycles expected to be performed on the flash memory blocks 140 in the corresponding flash memory device 130 before failure of the flash memory block 140 in the corresponding flash memory device 130. In FIG. 1, the flash memory device 130A has a higher projected life value than the projected life value of the flash memory device 130B.

At 230, a flash memory block on one of the plurality of flash memory devices is selected for the data operation based on the respective projected life values for the plurality of flash memory devices. The flash memory block may be selected such that a percentage of used life (e.g., the number of used cycles out of the projected life value) for all blocks remains within a range, for example 5% or 10%. For example, if a block has used 25% of its projected life (e.g., the number of cycles used equals 25% of the projected life value), the selected block may be selected such that after the data operation is performed, all the blocks have percentages of used life within 20-30%. Because at least two of the blocks have different projected life values, the blocks may have different used cycle counts, but still be within range of percentage of used life. Alternatively, the block with the highest percentage of remaining life (e.g., the number of cycles remaining out of the projected life value) may be selected such that after the data operation is performed, all blocks have a percentage of life remaining within a range, such as 5% or 10%.

A flash memory block 140 may be selected based on a remaining number of P/E cycles determined based on the projected life value and a P/E cycle count associated with the flash memory block 140. For instance, the remaining number of P/E cycles may be determined from the difference between the projected life value and the P/E cycle count for each flash memory block 140. In implementations, the flash memory block 140 having the highest remaining number of P/E cycles may then be selected. In implementations using a linked list, a flash memory block of a flash memory device near the beginning of the linked list may be selected. For example, a flash memory device near the beginning of the linked list may be selected, and a flash memory block of the selected memory device may be selected. The flash memory blocks may be ordered in respective data structures, such as linked lists. The flash memory blocks may be kept track of similar to the flash memory devices such that the linked lists may update after each data operation.

When one flash memory device 130 has a higher projected life value than another flash memory device 130, the flash memory blocks 140 of the flash memory device 130 having the higher projected life value may be selected more often for data operations than the flash memory blocks 140 of the flash memory device 130 having the lower projected life value. For instance, in FIG. 1 a rate at which the flash memory blocks 140 on the flash memory device 130A are selected compared to a rate at which the flash memory blocks 140 on the flash memory device 130B are selected may correspond to a ratio of the projected life value of the flash memory device 130A to the projected life value of the flash memory device 130B.

If the projected life value of the flash memory device 130A is 36,000 cycles, and the projected life value of the flash memory device 130B is 24,000 cycles, the ratio may be 3:2. The flash memory blocks 140 of the flash memory device 130A may be selected three times for every two times the flash memory blocks 140 of the flash memory device 130B are selected. For instance, the flash memory devices 130A and 130B may each be associated with counters which increment as each flash memory device is selected. In implementations using a linked list, the position of a flash memory device in the linked list may be based on the ratio such that flash memory devices having higher projected life values are generally placed more often—according to the ratio—near the beginning of the linked list compared to flash memory devices having lower projected life values. Alternatively, the linked list may be populated with multiple entries for each flash memory device based on the ratio, such as three entries for the flash memory device 130A and two entries for the flash memory device 130B.

The controller 120 may generally adhere to the 3:2 ratio, although the actual selections may not strictly adhere to the 3:2 ratio due to other considerations which may take precedence over wear leveling. Even if a flash memory device 130 is a candidate for selection based on the projected life value, the data operation may require another flash memory device 130 to be selected. For example, in a GC operation, the flash memory device 130B (having the lower projected life value) may be selected over the flash memory device 130A (having the higher projected life value) if the flash memory device 130B contains a higher percentage of invalid memory locations than the flash memory device 130A.

After the controller 120 selects a flash memory block 140, the controller 120 may perform the data operation on the flash memory block 140. The data operation may be a GC process, a write operation, or other maintenance operation. Characteristics and/or parameters for the flash memory device 130 corresponding to the selected flash memory block 140 may be updated. For instance, P/E cycle count or remaining cycle count may be updated. Alternatively, the position of the flash memory device 130 in the linked list may be adjusted based on the ratio.

FIG. 3A shows a table 310 of P/E cycles for two blocks from different flash memory devices in a simplified example of an even wear leveling scheme. Block 1 has a projected life value of 24K, and Block 2 has a projected life value of 36K. However, the manufacturer life value for each block is 30K cycles such that a total usage of 60K cycles is expected for the device. At the start, in which 0 P/E cycles have elapsed, Block 1 has 24K cycles remaining and 0 cycles used. The cycles remaining may be calculated by subtracting the cycles used from the projected life value. Block 2 has 36K cycles remaining and 0 cycles used. After 24K cycles have elapsed, the 24K cycles have been evenly distributed between Block 1 and Block 2, such that each block has 12K cycles used. After 24K more cycles (at 48K cycles), the cycles have been evenly distributed again such that each block has 24K cycles used. However, Block 1 has 0 cycles remaining Performance for the next 24K cycles is halved because Block 1 is no longer available. In other words, full performance may be available for only the first 48K cycles. Alternatively, if the manufacturer life value was 24K cycles (for a total usage of 48K cycles for the device), then after the 48K cycles, the cycles of Block 2 beyond 24K cycles would remain unused.

FIG. 3B shows a table 320 of the 60K P/E cycles for the two blocks in FIG. 3A in a simplified example of an optimal wear leveling scheme according to the subject technology. At the start, in which 0 P/E cycles have elapsed, Block 1 has 24K cycles remaining and 0 cycles used. Block 2 has 36K cycles remaining and 0 cycles used. After 20K cycles have elapsed, the 20K cycles have been distributed between Block 1 and Block 2 based on the respective projected life values, such that Block 1 has 8K cycles used and Block 2 has 12K cycles used. The ratio of 8K:12K (2:3) corresponds to the projected life values 24K:36K (2:3). After 20K more cycles (at 40K cycles), the cycles have been distributed by projected life values again such that Block 1 has 16K cycles used, and Block 2 has 24K cycles used. The usage 16:24 corresponds to the 2:3 ratio. After another 20K cycles (at 60K cycles), both blocks have 0 cycles remaining. In other words, full performance may be available for entire 60K cycle life of the flash storage system. Therefore, unlike even wear leveling schemes, the optimal wear leveling scheme uses the projected life values to utilize more cycles from the blocks.

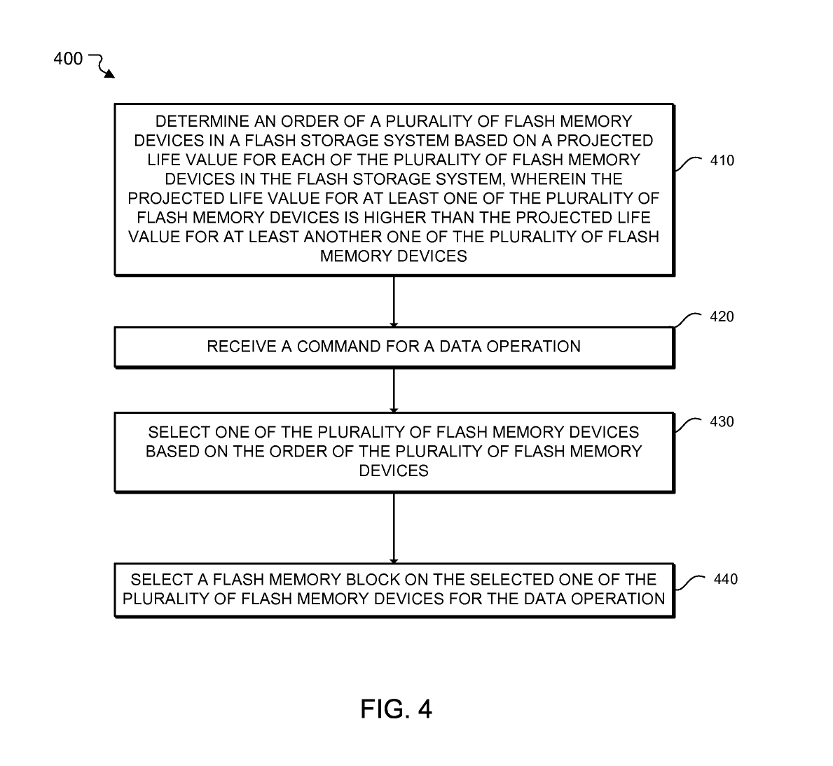

FIG. 4 shows a flowchart 400 for a wear leveling scheme according to aspects of the subject technology. The process in FIG. 4 may be performed, for example, by the controller 120 of the flash storage system 110. The flash storage system 110 is assembled with a plurality of flash memory devices 130 having the same or similar manufacturer life value. Each flash memory device 130 is individually tested with the high voltage test to determine respective projected life values, which is stored in the memory 125, and may be stored in a designated flash memory block 140 associated with the memory 125. The projected life values may be stored with respect to each flash memory device 130 (such that the projected life value is propagated or otherwise associated with respective flash memory blocks 140) or stored with respect to each flash memory block 140 based on the corresponding flash memory device 130. At least one of the projected life values is different from the manufacturer life value. For instance, the projected life value of the flash memory device 130A is higher than the manufacturer life value.

At 410, an order of flash memory devices in a flash storage system determined based on respective projected life values for each flash memory device. At least one of the flash memory devices has a higher projected life value than that of at least another one of the plurality of flash memory devices. The controller 120 may maintain an ordered list of flash memory devices 130 based on projected life values. A position of the flash memory devices 130 in the ordered list may be based on projected life values such that flash memory devices having more remaining life cycles may be positioned near a beginning of the linked list and are more likely to be selected for a data operation.

At 420, a command for a data operation is received. For example, the controller 120 may receive a write or erase command. At 430, one of the flash memory devices is selected based on the order of the flash memory devices. For example, the controller 120 may select the first flash memory device 130 in the linked list. At 440, a flash memory block on the selected flash memory device is selected for the data operation. For example, the controller 120 may maintain linked lists for the flash memory blocks 140 of each flash memory device 130, which may be ordered based on projected life values similar to the linked list of the flash memory devices. During or after the data operation is performed, the order of the flash memory devices may be updated. For example, the controller 120 may move the selected flash memory block 130 closer to an end of the linked list based on remaining cycles in comparison to remaining cycles of the other flash memory blocks. The controller 120 may also similarly update linked lists of the flash memory blocks.

The various illustrative blocks, modules, elements, components, methods, and algorithms described herein may be implemented as electronic hardware, computer software, or combinations of both. To illustrate this interchangeability of hardware and software, various illustrative blocks, modules, elements, components, methods, and algorithms have been described above generally in terms of their functionality. Whether such functionality is implemented as hardware or software depends upon the particular application and design constraints imposed on the overall system. The described functionality may be implemented in varying ways for each particular application. Various components and blocks may be arranged differently (e.g., arranged in a different order, or partitioned in a different way) all without departing from the scope of the subject technology.

It is understood that the specific order or hierarchy of steps in the processes disclosed is an illustration of exemplary approaches. Based upon design preferences, it is understood that the specific order or hierarchy of steps in the processes may be rearranged. Some of the steps may be performed simultaneously. The accompanying method claims present elements of the various steps in a sample order, and are not meant to be limited to the specific order or hierarchy presented.

The previous description is provided to enable any person skilled in the art to practice the various aspects described herein. Various modifications to these aspects will be readily apparent to those skilled in the art, and the generic principles defined herein may be applied to other aspects. Thus, the claims are not intended to be limited to the aspects shown herein, but is to be accorded the full scope consistent with the language claims, wherein reference to an element in the singular is not intended to mean “one and only one” unless specifically so stated, but rather “one or more.” Unless specifically stated otherwise, the term “some” refers to one or more. Pronouns in the masculine (e.g., his) include the feminine and neuter gender (e.g., her and its) and vice versa. Headings and subheadings, if any, are used for convenience only and do not limit the invention.

A phrase such as an “aspect” does not imply that such aspect is essential to the subject technology or that such aspect applies to all configurations of the subject technology. A disclosure relating to an aspect may apply to all configurations, or one or more configurations. A phrase such as an aspect may refer to one or more aspects and vice versa. A phrase such as a “configuration” does not imply that such configuration is essential to the subject technology or that such configuration applies to all configurations of the subject technology. A disclosure relating to a configuration may apply to all configurations, or one or more configurations. A phrase such a configuration may refer to one or more configurations and vice versa.

The word “exemplary” is used herein to mean “serving as an example or illustration.” Any aspect or design described herein as “exemplary” is not necessarily to be construed as preferred or advantageous over other aspects or designs.

All structural and functional equivalents to the elements of the various aspects described throughout this disclosure that are known or later come to be known to those of ordinary skill in the art are expressly incorporated herein by reference and are intended to be encompassed by the claims. Moreover, nothing disclosed herein is intended to be dedicated to the public regardless of whether such disclosure is explicitly recited in the claims. No claim element is to be construed under the provisions of 35 U.S.C. §112, sixth paragraph, unless the element is expressly recited using the phrase “means for” or, in the case of a method claim, the element is recited using the phrase “step for.” Furthermore, to the extent that the term “include,” “have,” or the like is used in the description or the claims, such term is intended to be inclusive in a manner similar to the term “comprise” as “comprise” is interpreted when employed as a transitional word in a claim.

What is claimed is:

1. A machine-implemented method for managing a flash storage system, comprising:
receiving a command for a data operation;
determining a projected life value for each of a plurality of flash memory devices in the flash storage system, wherein the projected life value for at least one of the plurality of flash memory devices is higher than the projected life value for at least another one of the plurality of flash memory devices; and
selecting a flash memory block on one of the plurality of flash memory devices for the data operation based on the respective projected life values for the plurality of flash memory devices.

2. The machine-implemented method for managing a flash storage system according to claim 1, wherein the projected life value for a respective flash memory device is associated with each flash memory block on the respective flash memory device, and wherein the projected life value is a number of program-erase cycles expected to be performed on flash memory blocks in the corresponding flash memory device before failure of the flash memory blocks in the corresponding flash memory device.

3. The machine-implemented method for managing a flash storage system according to claim 2, wherein the flash memory block is selected based on a remaining number of program-erase cycles determined based on the projected life value and a program-erase cycle count associated with the flash memory block.

4. The machine-implemented method for managing a flash storage system according to claim 1, wherein flash memory blocks on the at least one of the plurality of flash memory devices are selected more often for data operations than flash memory blocks on the at least another one of the plurality of flash memory devices.

5. The machine-implemented method for managing a flash storage system according to claim 4, wherein a rate at which the flash memory blocks on the at least one of the plurality of flash memory devices are selected compared to a rate at which the flash memory blocks on the at least another one of the plurality of flash memory devices corresponds to a ratio of the projected life values of the at least one of the plurality of flash memory devices and the at least another one of the plurality of flash memory devices.

6. The machine-implemented method for managing a flash storage system according to claim 1, further comprising performing the data operation on the selected flash memory block, wherein the data operation comprises a garbage collection process to reclaim invalid memory locations in the selected flash memory block or a write operation to write host data received from a host to the selected flash memory block.

7. The machine-implemented method for managing a flash storage system according to claim 1, wherein the projected life value for each of the plurality of flash memory devices is based on a test value measured from a respective test flash memory block in each of the plurality of flash memory devices.

8. A flash storage system, comprising:
a plurality of flash memory devices, each of the plurality of flash memory devices having a projected life value, wherein the projected life value of at least one of the plurality of flash memory devices is higher than the projected life value of at least another one of the plurality of flash memory devices; and
a controller configured to:
receive a command for a data operation; and
select a flash memory block on one of the plurality of flash memory devices for the data operation based on the respective projected life values of the plurality of flash memory devices comprising a plurality of flash memory blocks.

9. The flash storage system according to claim 8, wherein the projected life value for a respective flash memory device is associated with each flash memory block on the respective flash memory device, and
wherein the projected life value is a number of program-erase cycles expected to be performed on flash memory blocks in the corresponding flash memory device before failure of the flash memory blocks in the corresponding flash memory device.

10. The flash storage system according to claim 9, wherein the flash memory block is selected based on a remaining number of program-erase cycles determined based on the projected life value and a program-erase cycle count associated with the flash memory block.

11. The flash storage system according to claim 8, wherein flash memory blocks on the at least one of the plurality of flash memory devices are selected more often for data operations than flash memory blocks on the at least another one of the plurality of flash memory devices.

12. The flash storage system according to claim 11, wherein a rate at which the flash memory blocks on the at least one of the plurality of flash memory devices are selected compared to a rate at which the flash memory blocks on the at least another one of the plurality of flash memory devices corresponds to a ratio of the projected life values of the at least one of the plurality of flash memory devices and the at least another one of the plurality of flash memory devices.

13. The flash storage system according to claim 8, wherein the controller is further configured to perform the data operation on the selected flash memory block, wherein the data operation comprises a garbage collection process to reclaim invalid memory locations in the selected flash memory block or a write operation to write host data received from a host to the selected flash memory block.

14. The flash storage system according to claim 8, wherein the projected life value for each of the plurality of flash memory devices is based on a test value measured from a respective test flash memory block in each of the plurality of flash memory devices.

15. A machine-readable media encoded with executable instructions which, when executed by a processor, cause the processor to perform operations comprising:
determining an order of a plurality of flash memory devices in a flash storage system based on a projected life value for each of the plurality of flash memory devices in the flash storage system, wherein the projected life value of at least one of the plurality of flash memory devices is higher than the projected life value of at least another one of the plurality of flash memory devices;
receiving a command for a data operation;
selecting one of the plurality of flash memory devices based on the order of the plurality of flash memory devices; and
selecting a flash memory block on the selected one of the plurality of flash memory devices for the data operation.

16. The machine-readable media according to claim 15, wherein the projected life value for a respective flash memory device is associated with each flash memory block on the respective flash memory device, and
wherein the projected life value is a number of program-erase cycles expected to be performed on flash memory blocks in the corresponding flash memory device before failure of the flash memory blocks in the corresponding flash memory device.

17. The machine-readable media according to claim 16, wherein the order is determined based on a remaining number of program-erase cycles determined based on the projected life value and a program-erase cycle count associated with the flash memory block.

18. The machine-readable media according to claim 15, wherein flash memory blocks on the at least one of the plurality of flash memory devices are selected more often for data operations than flash memory blocks on the at least another one of the plurality of flash memory devices.

19. The machine-readable media according to claim 18, wherein a rate at which the flash memory blocks on the at least one of the plurality of flash memory devices are selected compared to a rate at which the flash memory blocks on the at least another one of the plurality of flash memory devices corresponds to a ratio of the projected life values of the at least one of the plurality of flash memory devices and the at least another one of the plurality of flash memory devices.

20. The machine-readable media according to claim 15, wherein the projected life value for each of the plurality of flash memory devices is based on a test value measured from a respective test flash memory block in each of the plurality of flash memory devices.
